(19) United States
(12) Patent Application Publication
(10) Pub. No.: US 2026/0370193 A1
(43) Pub. Date: Nov. 19, 2026

(54) IMPEDANCE OPTIMIZATION TECHNIQUE FOR SPACE-CONSTRAINED DISTRIBUTED AMPLIFIER

(71) Applicant: MACOM Technology Solutions Holdings, Inc., Lowell, MA (US)

(72) Inventors: Duy NGUYEN, Lowell, MA (US); Trong PHAN, Lowell, MA (US)

(21) Appl. No.: 19/209,998

(22) Filed: May 16, 2025

(51) Int. Cl. H03F 1/56; H03F 3/19; H05K 1/02

(52) U.S. Cl. CPC H03F 1/56; H03F 3/19; H05K 1/0219; H05K 1/0298; H03F 2200/451

(57) ABSTRACT

The present disclosure is generally directed to circuits, and in particular, to amplifier circuits and multi-layer printed circuit boards. More specifically, the disclosure is directed to RF shielding in a multilayer circuit, integrated chip or PCB having transmission lines. Even more specifically, the disclosure is directed to improving circuit performance though the addition of RF shielding to change the impedance and effective electrical length of one or more transmission lines in distributed amplifier circuit.

### FIELD

The present disclosure is generally directed to circuits, and in particular, to amplifier circuits, fully integrated circuits, and multi-layer printed circuit boards. More specifically, the disclosure is directed to RF shielding in a multilayer PCB or fully integrated circuit having transmission lines. Even more specifically, the disclosure is directed to improving circuit performance though the addition of RF shielding to change the impedance and electrical length of a transmission line in an integrated circuit, chip design, PCB and/or the like.

### BACKGROUND

The background description includes information that may be useful in understanding the present inventive subject matter. It is not an admission that any of the information provided herein is prior art or relevant to the presently claimed disclosure, or that any publication specifically or implicitly referenced is prior art.

Wide bandwidth amplifiers can be used in, for example, optical drivers for transmission lines, with some of these wide bandwidth amplifiers having a bandwidth of greater than 90 GHz. These amplifiers (and in general many electrical circuits) can be implemented on an integrated circuit, Printed Circuit Board (PCB), or the like, with components such as amplifier(s), transmission lines, inductors, capacitors, resistors, and associated components.

A transmission line is one type of interconnection found on these integrated circuits, chips and PCBs, and is used to transmit electrical signals. The transmission line includes a signal trace (often made of copper) and a return path, which is typically a ground plane, separated by a dielectric material. These transmission lines can carry high-frequency signals and are referred to as transmission lines as they behave in a similar manner to conventional transmission lines with wave propagation and impedance characteristics.

Some of the characteristics associated with transmission lines are that in an ideal environment, the transmission line should exhibit a uniform impedance. In other words, at high frequencies, the transmission lines should maintain a consistent impedance along their length to prevent signal reflections, distortions and other undesirable artifacts.

Generally, there are two common types of transmission line-microstrip and stripline. The microstrip version of the transmission line has a signal trace on a layer of a PCB, with a ground plane acting as the return path. A stripline transmission line has a signal trace embedded between two ground planes, with the ground planes providing the return path.

Understanding the behavior and designing transmission lines is difficult because ignoring transmission line effects, such as those mentioned above, can lead to issues such as signal reflections, crosstalk, electromagnetic interference (EMI), and electromagnetic noise, which can negatively impact signal quality, bandwidth and reliability.

Any radio frequency (RF) shielding structure included in or on the PCB can change the electrical length of a transmission line(s) therein, can lower insertion loss and can also improve bandwidth, with the opposite also being true if not designed properly. As used herein, the terms electrical length and effective electrical length are used interchangeably. A discussion of the meaning of these terms can be found here: en.wikipedia.org/wiki/Electrical_length.

Traditionally, two transmission lines are implemented on the same layer of a multilayer PCB or integrated circuit, and there are no proximity shielding structures (i.e., the distance from the transmission line to any shielding is larger than a distance from the conductor to the ground plane underneath.)

In another implementation scenario, two transmission lines can be on different layers of the PCB, and coplanar wave guide shielding structures can be employed. Coplanar waveguide (CPW) shielding includes techniques that are designed to reduce unwanted electromagnetic radiation and interference, often achieved using ground planes or other metallic shields. A ground plane, often a continuous copper layer on the PCB serves as a return path for the signal and also provides shielding. Additionally, top and bottom ground plane shields on the PCB can be used to further reduce radiation and improve circuit isolation. A ground plane on the same layer as the signal trace, or on a separate layer, forms a return path for current, which in turn reduces radiated energy. The ground plane also serves as a shield against electromagnetic interference.

In another scenario, two transmission lines are on different layers. Multi-layer shielding structures are introduced and the spacing between the transmission lines and the RF shielding is optimized for the best impedance/inductance and performance at high frequency.

The transmission lines being on different layers and multi-layer shielding can change the impedance and effective electrical length of the line. This arrangement can also make the impedance more consistent over frequency (i.e. enhance bandwidth) and lower insertion loss.

### SUMMARY

However, with wide bandwidth distributed amplifier circuits, where transmission lines connect the different stages, there can be significant space constraints. These distributed amplifier layouts usually have very tight dimensional constraints on the space available for the transmission lines. Additionally, at least the physical length for the input and output transmission line are typically the same because the distance between gain unit cells is fixed.

However, from a performance perspective, the input and output transmission lines typically need to have very different electrical lengths and characteristic impedances to achieve the desired performance for the distributed amplifier. Designing two transmission lines that have the same physical length, but very different electrical length is challenging, especially at high frequency, where the distributed amplifier needs to maintain a very wide bandwidth.

Moreover, transmission line coupling (i.e. inter-transmission line interference) creates unwanted effects on performance at high frequency. The coupling between input and output in the distributed structures can also potentially cause oscillations if proper shielding is not employed.

One embodiment addresses at least these challenges through the following. And these techniques can be applied regardless of whether the transmission lines are the same physical length or not.

First, the input and output lines are designed using two different metal layers.

Second, a RF shield, which can be multi-layer, is placed in the proximity of the input and output lines. The RF shield has two functions: 1) help adjust and optimize the impedance and (effective) electrical length of each input and output transmission line of the distributed amplifier. The input and output lines are no longer characterized as pure microstrip lines, but rather they can now be characterized as composite microstrip/CPW (co-planar) transmission lines, and 2) the shielding can significantly reduce the coupling effect between transmission lines.

Up to six or more metal layers and vias layers can be connected from the ground plane (or power plane) up to the top metal to provide RF shielding for the transmission lines. The distance (spacing) between the RF shield and the transmission line can be adjusted and optimized as discussed herein to achieve a certain required impedance and effective electrical length.

The RF shield can be placed at least at the input lines, the output lines, and between the positive side and the negative side transmission lines, with each of these shields having a different impact on one or more of the impedance, electrical length of the transmission line, and coupling.

Another exemplary embodiment provides a method to design an integrated circuit, chip, and/or PCB that achieves higher performance, especially wide bandwidth, high frequency distributed amplifier circuits. Specifically, one starts by determining the impedance and effective electrical length needed for each input and output transmission line from a schematic, design document, or the like. Next, the individual amplifier cells are laid out on the PCB and the physical distances between the various gain unit cells are determined. Then, an assessment can be made, for example through modelling, as to whether transmission lines have too much coupling. Some examples of modelling software that can be used to perform this modelling are electromagnetic (EM) simulation tools such as HFSS, Cadence EMX, AXIEM, Keysight ADS Momentum. If there is too much transmission line coupling, one or more of the input and output lines or positive/negative lines can be moved to a different layer.

RF shielding is then added for the transmission lines using, for example, a conductive material such as copper, gold, or comparable material. This RF shielding can extend partially, wholly or even further alongside the associated transmission line(s) either on the same layer of the PCB and/or on a different layer(s) of the PCB, with parameters such as the length, width, thickness, placement and material of the shielding all being configurable/adjustable. This configurability allows the impedance and effective electrical length of each transmission line to be adjusted and optionally optimized for the circuit. As one example, shielding could be placed partially alongside a transmission line, and additional shielding placed on a layer above and a layer below the transmission line. In general, shielding can be placed at any one or more locations above, below, and/or on either side of a transmission line.

With this first RF shielding design, a simulation can be run that estimates the impedance and effective electrical length of each transmission line. For each transmission line that does not match the design specification of the circuit, one adds, removes, adjusts or otherwise modifies one or more of the above parameters and repeats the simulation such that one or more of the impedance and effective electrical length of the transmission line is (substantially) achieved.

This process is iterated until the impedance and effective electrical length of each transmission line has been achieved.

One can then optionally run a full 3D electromagnetic simulation of the layout, using, for example, HFSS, Cadence EMX, AXIEM, Keysight ADS Momentum, of one stage. When the results are acceptable, the design of that stage can be finalized, and the above process steps repeated for the other stages.

These and other exemplary advantages, techniques and designs will be described in greater detail herein.

The phrases “at least one,” “one or more,” and “and/or,” as used herein, are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

Unless otherwise indicated, all numbers expressing quantities, dimensions, conditions, and so forth used in the specification and claims are to be understood as being modified in all instances by the term “about.”

The use of “substantially” in the present disclosure, when referring to a measurable quantity (e.g., a diameter or other distance) and used for purposes of comparison, is intended to mean within 5% of the comparative quantity. The terms “substantially similar to,” “substantially the same as,” and “substantially equal to,” as used herein, should be interpreted as if explicitly reciting and encompassing the special case in which the items of comparison are “similar to,” “the same as” and “equal to,” respectively.

As used herein, unless otherwise specified, the terms “about,” “approximately,” etc., when used in relation to numerical limitations or ranges, mean that the recited limitation or range may vary by up to 10%. By way of non-limiting example, “about 750” can mean as little as 675 or as much as 825, or any value or fractional value therebetween. When used in relation to ratios or relationships between two or more numerical limitations or ranges, the terms “about,” “approximately,” etc., mean that each of the limitations or ranges may vary by up to 10%; by way of non-limiting example, a statement that two quantities are “approximately equal” can mean that a ratio between the two quantities is as little as 0.9:1.1 or as much as 1.1:0.9 (or any value therebetween), and a statement that a four-way ratio is “about 5:3:1:1” can mean that the first number in the ratio can be any value of at least 4.5 and no more than 5.5, the second number in the ratio can be any value of at least 2.7 and no more than 3.3, and so on.

The term “a” or “an” entity, as used herein, refers to one or more of that entity. As such, the terms “a” (or “an”), “one or more” and “at least one” can be used interchangeably herein.

The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein. The use of “engaged with” and variations thereof herein is meant to encompass any direct or indirect connections between components.

It shall be understood that the term “means” as used herein shall be given its broadest possible interpretation in accordance with 35 U.S.C. § 112(f). Accordingly, a claim incorporating the term “means” shall cover all structures, materials, or acts set forth herein, and all of the equivalents thereof. Further, the structures, materials, or acts and the equivalents thereof shall include all those described in the summary, brief description of the drawings, detailed description, abstract, and claims themselves.

All external references are hereby incorporated by reference in their entirety whether explicitly stated or not.

These and other advantages will be apparent from this disclosure. The above-described embodiments, objectives, aspects and configurations are neither complete nor exhaustive. The Summary is neither intended nor should it be construed as being representative of the full extent and scope of the present disclosure. Moreover, references made herein to “the present disclosure,” or aspects thereof should be understood to mean certain embodiments of the present disclosure and should not necessarily be construed as limiting all embodiments to a particular description. The present disclosure is set forth in various levels of detail in the Summary as well as in the attached drawings and the Detailed Description and no limitation as to the scope of the present disclosure is intended by either the inclusion or non-inclusion of elements, components, etc. in this Summary. Additional aspects of the present disclosure will become more readily apparent from the Detailed Description, particularly when taken together with the drawings.

It is to be appreciated that any embodiment, feature, or aspect described herein can be claimed in combination with any other embodiment(s), feature(s), or aspect(s) as described herein, regardless of whether the features or aspects come from the same described embodiment. For example, any one or more aspects described herein can be combined with any other one or more aspects described herein. In addition, any one or more embodiment(s) or feature(s) described herein can be combined with any other one or more embodiment(s) or feature(s) described herein. Similarly, any one or more portions of the embodiment(s) or feature(s) described herein can be combined with any other one or more portions of the embodiment(s) or feature(s) described herein.

### BRIEF DESCRIPTION OF THE DRAWINGS

Those of skill in the art will recognize that the following description is merely illustrative of the principles of the disclosure, which may be applied in various ways to provide many different alternative embodiments. This description is made to illustrate the general principles of the teachings of this disclosure and is not meant to limit the inventive concepts disclosed herein.

The accompanying drawings, which are incorporated in and constitute a part of the specification, illustrate embodiments and together with the general description of the disclosure given above and the detailed description of the drawings given below, serve to explain the principles of the disclosure.

FIG. 1 illustrates, in block diagram form, an exemplary schematic of a differential distributed amplifier design.

FIG. 2 illustrates, in block diagram form, an exemplary layout of a distributed amplifier design.

FIG. 3 illustrates the exemplary layout of a distributed amplifier design including a plurality of RF shielding according to one exemplary embodiment. Here, the spacing between the input shielding and input line is different from the spacing between output shielding and output line. The input line and output line can therefore achieve different effective electrical lengths and impedances while having a similar, if not the same, physical length.

FIG. 3 A-C show exemplary iterative (hypothetical) intermediary designs that resulted in the final design shown in FIG. 3.

FIG. 4 illustrates an exemplary Smith Chart showing the improved characteristics of the circuit in FIG. 3. The Smith chart can be used to simultaneously display multiple parameters including impedances, admittances, reflection coefficients, Sm scattering parameters, noise figure circles, constant gain contours and regions for unconditional stability. Blue indicates the results of a first iteration of the techniques disclosed herein, green the second iteration and red the third iteration.

FIG. 5 illustrates an exemplary comparison of inductance to frequency for the circuit in FIG. 3, with the added RF shielding, again where blue indicates the results of a first iteration of the techniques disclosed herein, green the second iteration and red the third iteration.

FIG. 6 illustrates an exemplary comparison of insertion loss to frequency for the circuit in FIG. 3, with the added RF shielding, again where blue indicates the results of a first iteration of the techniques disclosed herein, green the second iteration and red the third iteration. As lower insertion loss is considered better, the top line (third iteration) shows the best performance.

FIG. 7 illustrates an exemplary graph of how small signal performance can be improved in relation to overall performance of an exemplary amplifier utilizing the techniques disclosed herein where a conventional circuit with no shielding is shown in dashed-line, and the new design shown in solid-line. Uniformity represents better performance.

FIG. 8 is a flowchart illustrating an exemplary method for improving RF shielding according to one exemplary embodiment.

It should be understood that the drawings are not necessarily to scale, and various dimensions may be altered. In certain instances, details that are not necessary for an understanding of the disclosure or that render other details difficult to perceive may have been omitted. It should be understood, of course, that the disclosure is not necessarily limited to the particular embodiments illustrated herein.

### DETAILED DESCRIPTION

Although the following text sets forth a detailed description of numerous different embodiments, it should be understood that the legal scope of the description is defined by the words of the claims set forth at the end of this disclosure. The Detailed Description is to be construed as exemplary only and does not describe every possible embodiment since describing every possible embodiment would be impractical, if not impossible. Numerous alternative embodiments could be implemented, using either current technology or technology developed after the filing date of this patent, which would still fall within the scope of the claims. Additionally, any combination of features shown in the various figures can be used to create additional embodiments of the present disclosure. Thus, dimensions, aspects, and features of one embodiment can be combined with dimensions, aspects, and features of another embodiment to create the claimed embodiment.

It is with respect to the above-noted challenges that embodiments of the present disclosure were contemplated. In particular, a system, circuits, and method of designing and providing such circuits are provided that solve the drawbacks associated with existing amplifier circuits, driver circuits, equalizer circuits or in general at least any circuit that has transmission lines.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in connection with high-speed communications amplifiers for copper or fiber, it should be appreciated that the claims are not limited to high speed electrical and optical or electro-optical communications technologies. Indeed, the shielding configuration(s) depicted and described herein may be utilized in any number of applications or in general on any PCB or similar circuit board and can be especially useful in circuits utilizing an amplifier (e.g., transmitter applications, receiver applications, filtering applications, etc.) and transmission lines. Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, or combinations thereof.

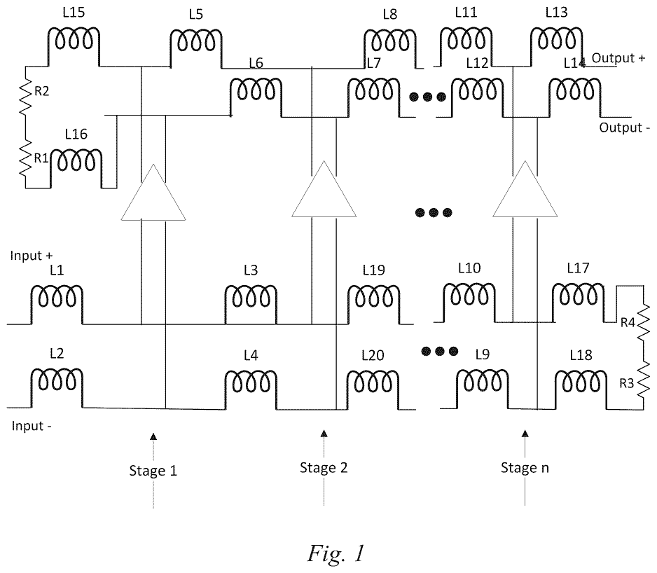

FIG. 1 illustrates, in block diagram form, an exemplary schematic of a distributed amplifier design. The distributed amplifier includes a plurality of components including inductors, active device(s) (such as a transistor(s)) and transmission lines. The output of multiple stages (each stage at least includes a transistor and two transmission lines) is combined to generate a wider bandwidth output than what a single stage wideband amplifier can produce. Connecting the active devices are transmission lines, and it is these transmission lines that, due to their physical proximity, generate cross talk and interference therebetween.

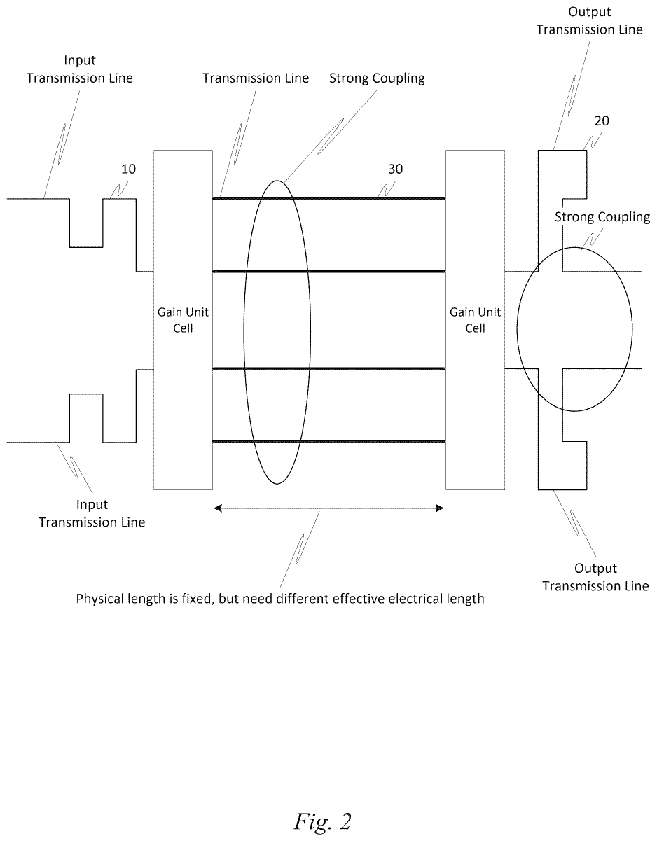

FIG. 2 illustrates, in block diagram form, an exemplary layout of a distributed amplifier design. The exemplary amplifier design includes a plurality of gain unit cells coupled with transmission lines as shown. Typically, due to such things a design constraints and physical size limitations of the circuit on the PCB and/or the PCB itself, the transmission lines have a physically fixed length and/or dimension. But as discussed, to improve performance, these transmission lines need to have different electrical lengths.

In exemplary FIG. 2, there are two input transmission lines 10, two output transmission lines 20 and a plurality of intermediary transmission lines 30. No shielding is present in FIG. 2, thus, there can be strong coupling between ones of the transmission lines as shown by the ellipses in the figure.

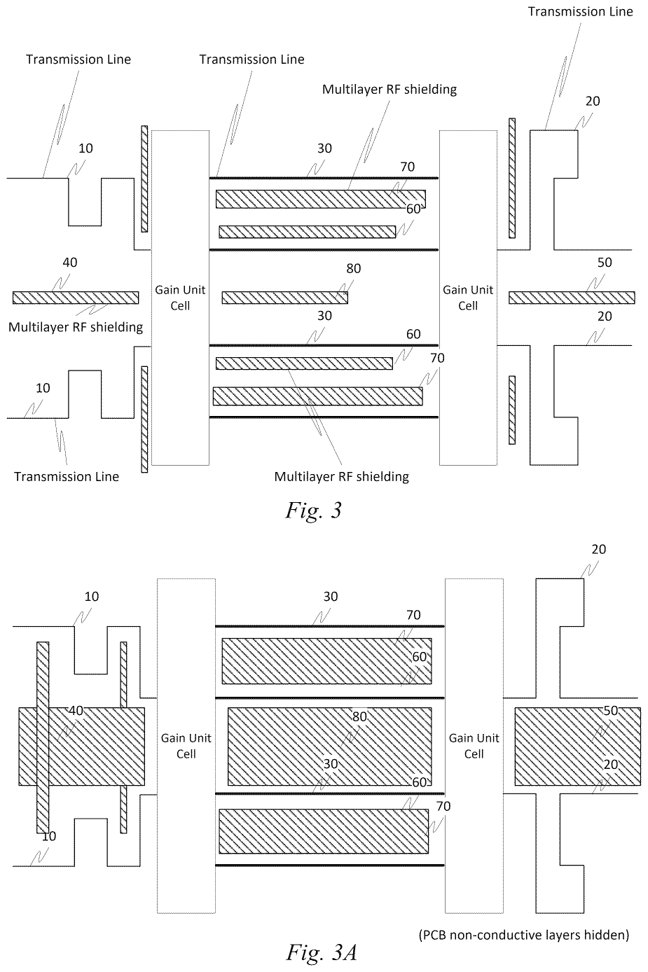

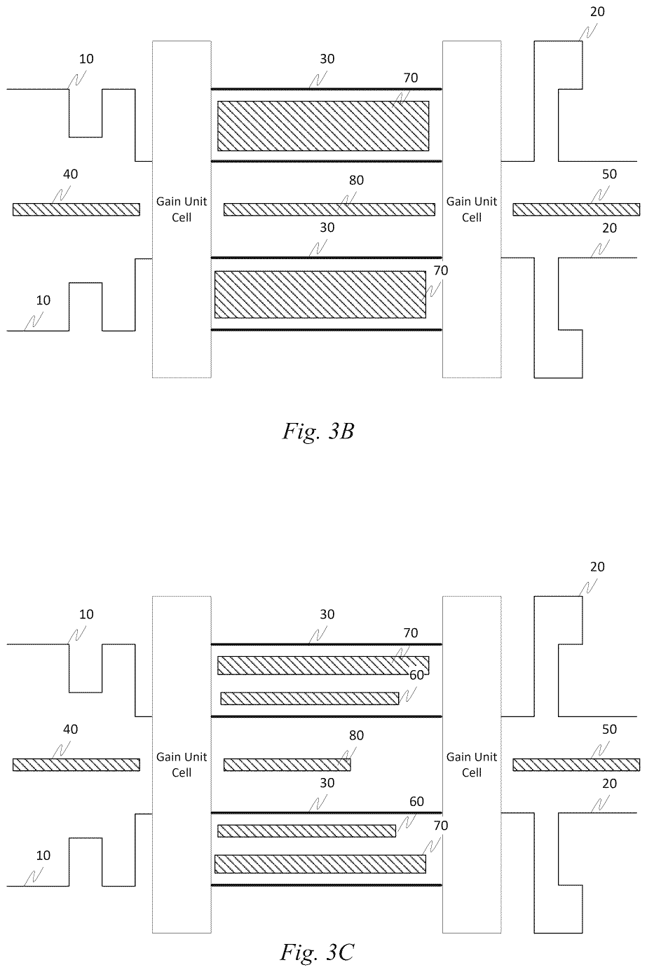

FIG. 3 illustrates the exemplary layout of a distributed amplifier design (similar to that in FIG. 2) including a plurality of RF shielding portions according to one exemplary embodiment.

While FIG. 3 is shown in 2 dimensions, it is to be appreciated that the circuit/chip/PCB can include multiple layers (discussed hereinafter) and the various transmission lines and shielding can be on different layer(s). As will be discussed, the designer can try various configurations to achieve the impedance and effective electrical length of the transmission lines by altering one or more of the placement, orientation, thickness, shape, layer, and proximity of the shielding to the transmission line(s) they are trying to modify the impedance and/or effective electrical length of.

In this exemplary configuration, the spacing between the input shielding 40 and input line 10 is different from the spacing between output shielding 50 and output line 20. The input line and output line can therefore achieve different effective electrical lengths and impedances while having a similar, if not the same, respective physical lengths.

As just one non-limiting example, the input transmission lines 10 and shielding 40 could be on a first circuit/chip/PCB layer, the output transmission lines 20 and shielding 50 on a different layer of the circuit/chip/PCB, and the intermediary transmission lines 30 being on yet another layer of the circuit/chip/PCB, with the shielding 70 being above that layer, the shielding 60 being below that layer and the shielding 80 being on that same layer. As is to be appreciated, there is an infinite number of possibilities for how the shielding and transmission lines could be configured based on such things as circuit type, circuit size, circuit layout, operating frequency, trace size, trace length, number of PCB layers, circuit construction, chip construction, number of components, number of transmission lines, number of amplifier stages, and the like.

This design could be achieved through iterating through multiple configurations of the shielding at different locations, layers, etc., with a goal of trying to match the design specifications of the circuit designer. For this hypothetical exemplary case, three iterations of the design were rendered, with the eventual final design shown in FIG. 3. FIG. 3A shows an exemplary first iteration where large blocks of shielding were placed between the transmission lines and above and below the input transmission lines. FIG. 3B shows a second iteration where block size was reduced and shapes changed, and FIG. 3C shows a third iteration where shielding on additional layers was added, shielding shape changed and shielding widths modified.

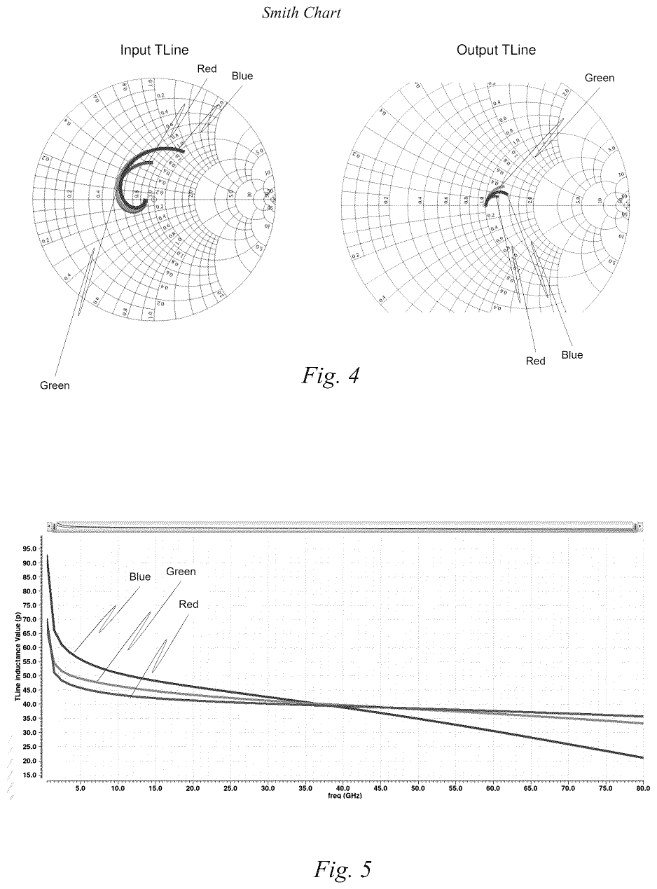

FIG. 4 illustrates an exemplary Smith Chart showing the (hypothetical) improved characteristics of the circuit in FIG. 3 as the various iterations (FIGS. 3A-3C) were run through a simulation. In the Smith Chart, blue indicates the results of a circuit with no shielding, i.e. FIG. 2. A first iteration of the shielding shown in FIG. 3A is shown by the green trace, and the results of the third iteration shown in FIG. 3C, represented by the red trace, which iteration provided the best results.

FIG. 5 illustrates an exemplary comparison of inductance to frequency for the circuit in FIG. 3, with the added RF shielding, again where blue indicates the results of a first iteration of the techniques disclosed herein, green the second iteration and red the third iteration. Here again, the third iteration provided the best results.

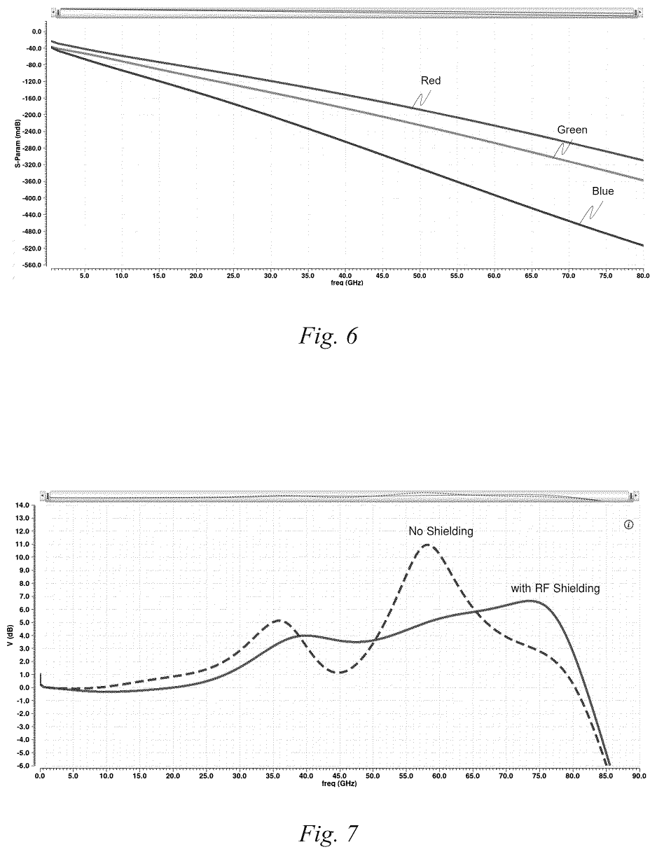

FIG. 6 illustrates an exemplary comparison of insertion loss (S-Parameter) to frequency for the circuit in FIG. 3, with the added RF shielding, again where blue indicates the results of a first iteration of the techniques disclosed herein, green the second iteration and red the third iteration. As lower insertion loss is considered better, the top line (third iteration) shows the best performance.

FIG. 7 illustrates an exemplary graph of how small signal performance can be improved in relation to overall performance of an exemplary amplifier utilizing the techniques disclosed herein where a conventional circuit with no shielding is shown by the dashed-line, and the new design shown by the solid-line. In this style of chart, uniformity represents better performance with the RF shielded circuit achieving better results.

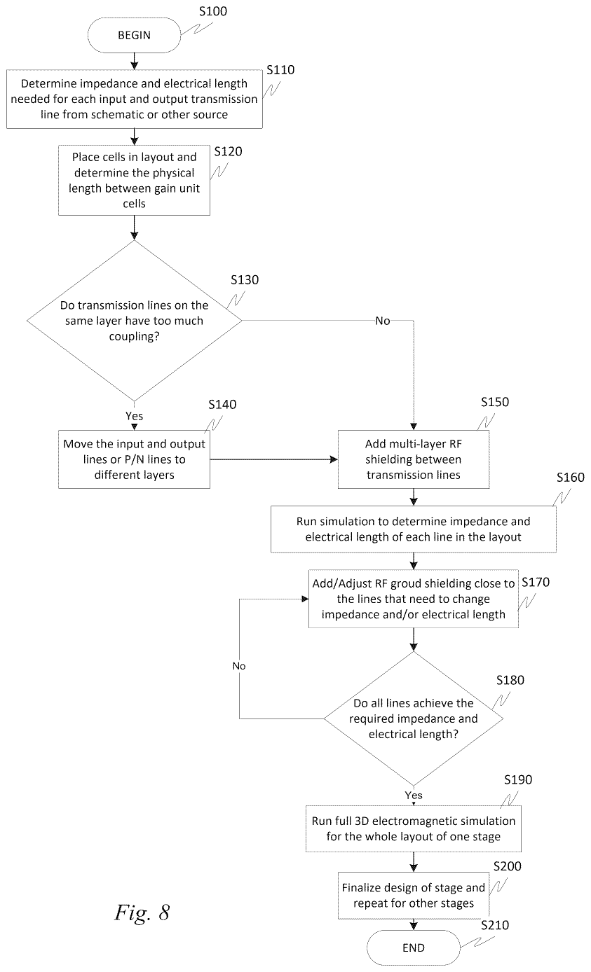

FIG. 8 is a flowchart illustrating an exemplary method for improving RF shielding according to one exemplary embodiment.

Control begins in step S100 and continues to step S110. In step S110, Specifically, the impedance and effective electrical length needed for each input and output transmission line is determined from a schematic, design document, engineer, or the like. Next, in step S120, the individual amplifier cells (or in general circuit components) are laid out on the PCB and the physical distances between the various gain unit cells determined. Then, in step S130, an assessment can be made, for example through modelling, as to whether transmission lines have too much coupling or cross-talk. Some examples of modelling software that can be used to perform this modelling are electromagnetic (EM) simulation tools such as HFSS, Cadence EMX, AXIEM, Keysight ADS Momentum.

If there is too much transmission line coupling, control continues to step S140 where one or more of the input and output lines or positive/negative lines can be moved to a different layer. Control then continues to step S150.

If transmission lines on the same layer don't have too much coupling, control continues to step S150.

In step S150, RF shielding is added between the transmission lines using, for example, a conductive material such as copper, gold, or comparable material. This RF shielding can extend partially, wholly or even further than the associated transmission line(s) with parameters such as the length, width, thickness, placement, orientation and material of the shielding all being configurable/adjustable. This configurability allows the impedance and effective electrical length of each transmission line to be adjusted and optionally optimized for the circuit.

Next, in step S160, with this first RF shielding design, a simulation can be run that estimates the impedance and effective electrical length of each transmission line. For each transmission line that does not match the design specification of the circuit, one adds, adjusts or otherwise modifies in step S170 one or more of the above parameters and repeats the simulation such that one or more of the impedance and effective electrical length of the transmission line is (substantially) achieved. This process is iterated in step S180 until the impedance and effective electrical length of each transmission line has been achieved. Control then continues to step S190.

In step S190, one can optionally run a full 3D electromagnetic simulation of the layout, using, for example, HFSS, Cadence EMX, AXIEM, Keysight ADS Momentum, of one stage. When the results are acceptable, the design of that stage can be finalized in step S200, and the above process steps repeated for the other stages that exist in the circuit. Control then continues to step S210 where the control sequence ends.

In accordance with another exemplary embodiment, the above process could be automated or semi-automated with the assistance of software, AI and/or machine learning where the desired effective electrical length and desired impedance are input parameters (along with the actual physical lengths a of the transmission lines and placement of other components), and altering one or more of the placement, orientation, thickness, shape, layer, and proximity of the shielding to the transmission line(s) to alter the impedance and/or effective electrical length of the transmission lines are design constraints, and the output would be the optimized circuit design with the appropriate shielding.

Exemplary aspects are directed toward:

An electronic device comprising:
one or more transmission lines arranged on a circuit, integrated chip, and/or printed circuit board (PCB);
shielding arranged relative to the one or more transmission lines, the shielding causing one or more of an impedance and effective electrical length of the one or more transmission lines to be altered; and
one or more ground planes, one or more positive lines and one or more negative lines.

Any of the above aspects, wherein the PCB is a multilayer PCB and the one or more transmission lines and the shielding are present on different layers of the PCB.

Any of the above aspects, wherein the electronic device is a distributed amplifier.

Any of the above aspects, wherein the shielding is RF shielding, and the shielding is present on a plurality of layers of the PCB.

Any of the above aspects, wherein the shielding is modified in a design stage by altering one or more of: a placement, orientation, thickness, shape, layer, and proximity of the shielding relative to an associated transmission line.

Any of the above aspects, wherein the electronic device is a multi-stage distributed amplifier, and there are multiple transmission lines between each stage.

Any of the above aspects, wherein at least two transmission lines are of the same physical length.

Any of the above aspects, wherein input and output transmission lines are on different layers of the PCB.

Any of the above aspects, wherein the electronic device is a space-constrained distributed amplifier, there are at least two input transmission lines, at least two output transmission lines and a plurality of inter-stage transmission lines, with shielding being associated with each of the at least two input transmission lines, each of the at least two output transmission lines and each of the plurality of inter-stage transmission lines.

A method of designing a circuit comprising:
determining an impedance and effective electrical length for each transmission line in a circuit;
determine, through simulation, whether transmission lines on a same layer of a circuit, chip, and/or printed circuit board are too coupled; and
adding or modifying multilayer shielding between transmission lines that are too coupled. Any of the above aspects, further comprising moving one or more of input transmission lines, output transmission lines, positive lines and negative lines to another layer of the PCB.

Any of the above aspects, further comprising iteratively modifying the shielding that is close to a transmission line that is too coupled.

Any of the above aspects, further comprising running a simulation to determine the impedance and effective electrical length for each transmission line.

Any of the above aspects, further comprising iterating the adding or modifying steps until a desired impedance and effective electrical length for each transmission line in the circuit is achieved.

Any of the above aspects, further comprising performing the steps for each stage of a multistage amplifier.

Any of the above aspects, further comprising determining a physical distance between each gain unit cell.

Any of the above aspects, wherein some of the transmission lines have a same physical length.

Any of the above aspects, wherein the circuit is a distributed amplifier with a plurality of transmission lines.

Any of the above aspects, further comprising running a 3D electromagnetic simulation for one or more portions of the circuit.

A non-transitory computer readable information storage media having stored thereon instructions, that when executed by a processor, cause to be performed a method comprising:
determining an impedance and effective electrical length for each transmission line in a circuit;
determine, through simulation, whether transmission lines on a same layer of a circuit, chip, and/or printed circuit board (PCB) are too coupled; and adding multilayer shielding between transmission lines that are too coupled.

Any one or more of the above aspects/embodiments as substantially disclosed herein.

Any one or more of the aspects/embodiments as substantially disclosed herein optionally in combination with any one or more other aspects/embodiments as substantially disclosed herein.

One or means adapted to perform any one or more of the above aspects/embodiments as substantially disclosed herein.

Any one or more of the features disclosed herein.

Any one or more of the features as substantially disclosed herein.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

While various embodiments of the present disclosure have been described in detail, it is apparent that modifications and alterations of those embodiments will occur to those skilled in the art. However, it is to be understood that such modifications and alterations are within the scope and spirit of the present disclosure, as set forth in the following claims. Further, the disclosure described herein is capable of other embodiments and of being practiced or of being carried out in various ways. It is to be understood that the phraseology and terminology used herein is for the purpose of description and should not be regarded as limiting.

1. An electronic device comprising:
one or more transmission lines arranged on a circuit, integrated chip or printed circuit board (PCB);
shielding arranged relative to the one or more transmission lines, the shielding causing one or more of an impedance and effective electrical length of the one or more transmission lines to be altered; and
one or more ground planes, one or more positive lines and one or more negative lines.

2. The device of claim 1, wherein the circuit, chip or PCB is a multilayer device and the one or more transmission lines and the shielding are present on different layers of the circuit, chip or PCB.

3. The device of claim 1, wherein the electronic device is a distributed amplifier.

4. The device of claim 1, wherein the shielding is RF shielding, and the shielding is present on a plurality of layers of the circuit, chip or PCB.

5. The device of claim 1, wherein the shielding is modified in a design stage by altering one or more of: a placement, orientation, thickness, shape, layer, and proximity of the shielding relative to an associated transmission line.

6. The device of claim 1, wherein the electronic device is a multi-stage distributed amplifier, and there are multiple transmission lines between each stage.

7. The device of claim 1, wherein at least two transmission lines are of the same physical length.

8. The device of claim 1, wherein input and output transmission lines are on different layers of the circuit, chip or PCB.

9. The device of claim 1, wherein the electronic device is a space-constrained distributed amplifier, there are at least two input transmission lines, at least two output transmission lines and a plurality of inter-stage transmission lines, with shielding being associated with each of the at least two input transmission lines, each of the at least two output transmission lines and each of the plurality of inter-stage transmission lines.

10. A method of designing a circuit comprising:
determining an impedance and effective electrical length for each transmission line in a circuit;
determine, through simulation, whether transmission lines on a same layer of a circuit, chip or printed circuit board (PCB) are too coupled; and
adding or modifying multilayer shielding between transmission lines that are too coupled.

11. The method of claim 10, further comprising moving one or more of input transmission lines, output transmission lines, positive lines and negative lines to another layer of the circuit, chip or PCB.

12. The method of claim 10, further comprising iteratively modifying the shielding that is close to a transmission line that is too coupled.

13. The method of claim 10, further comprising running a simulation to determine the impedance and effective electrical length for each transmission line.

14. The method of claim 13, further comprising iterating the adding or modifying steps until a desired impedance and effective electrical length for each transmission line in the circuit is achieved.

15. The method of claim 10, further comprising performing the steps for each stage of a multistage amplifier.

16. The method of claim 10, further comprising determining a physical distance between each gain unit cell.

17. The method of claim 10, wherein some of the transmission lines have a same physical length.

18. The method of claim 10, wherein the circuit is a distributed amplifier with a plurality of transmission lines.

19. The method of claim 10, further comprising running a 3D electromagnetic simulation for one or more portions of the circuit.

20. A non-transitory computer readable information storage media having stored thereon instructions, that when executed by a processor, cause to be performed a method comprising:
determining an impedance and effective electrical length for each transmission line in a circuit;
determine, through simulation, whether transmission lines on a same layer of a circuit, chip or printed circuit board (PCB) are too coupled; and
adding multilayer shielding between transmission lines that are too coupled.
